(19) United States
(12) Patent Application Publication
(10) Pub. No.: US 2026/0190656 A1
(43) Pub. Date: Jul. 2, 2026

(54) DISPLAY DEVICE

(71) Applicant: LG Display Co., Ltd., Seoul (KR)

(72) Inventor: Minkuk KIM, Paju-si (KR)

(73) Assignee: LG Display Co., Ltd., Seoul (KR)

(21) Appl. No.: 19/217,579

(22) Filed: May 23, 2025

(30) Foreign Application Priority Data
Dec. 31, 2024 (KR) 10-2024-0201810

(51) Int. Cl. H10K 59/124; H10K 59/131; H10K 59/40; H10K 102/00

(52) U.S. Cl. CPC H10K 59/124; H10K 59/131; H10K 59/40; H10K 2102/311

(57) ABSTRACT

The present disclosure is a display device capable of blocking moisture flow between a display area and a bendable area. The display device includes a substrate including display, non-display, and bendable areas; an insulating layer on the substrate; a first connection line on the insulating layer; a first planarization layer on the first connection line; a second connection line on the first planarization layer; a second planarization layer on the second connection line; a third planarization layer on the second planarization layer; a touch buffer layer on the third planarization layer; and a sealing layer on the touch buffer layer. Between the display area and the bendable area, a first groove and an adjacent second groove are formed in each of the touch buffer layer and the second planarization layer so as to be recessed downwardly from an upper surface thereof.

### CROSS-REFERENCE TO RELATED APPLICATION

Pursuant to 35 U.S.C. § 119(a), this application claims the benefit of an earlier filing date and right of priority to Korean Patent Application No. 10-2024-0201810 filed on Dec. 31, 2024 in the Korean Intellectual Property Office, the contents of which are incorporated by reference herein in their entirety.

### BACKGROUND

### Technical Field

The present disclosure relates to a display device, and more particularly, to a display device for preventing a crack generated between a display area and a bendable area and thus preventing moisture from flowing through therethrough.

### Description of the Related Art

An organic light-emitting display device may be folded or bent using a flexible substrate for various shapes. In order to enlarge a display area (Active Area: AA) of the display device and to reduce a bezel area, a pad to which a printed circuit board (PCB) is connected may be disposed under the display area DA. To this end, a bendable area BA in which the flexible substrate is bent may be disposed.

In the bendable area BA, a flexible substrate and a line and insulating films disposed on the substrate may be bent. In order to bend a display panel, a minimum number of insulating films and lines may be disposed in the bendable area. A connection portion for connecting the line of the bendable area to the line of each of the display area and the pad may be adjacent to the bendable area BA and thus may be vulnerable to moisture penetration.

### BRIEF SUMMARY

In the organic light-emitting display device, a driver (driver IC: DIC) is manufactured in a chip form and mounted on a non-active area or a non-display area NA of the display panel. In a PO (Plastic OLED) model, the driving chip DIC is pressed and bonded to a FOP (Film On Panel) pad located in the non-display area in a bonding process.

Moisture may be introduced into an area between the display area AA and the bendable area BA through a planarization layer made of an organic material, and contacts metal electrodes such that corrosion occurs in contact holes of the electrodes due to a Galvanic reaction.

In addition, hydrogen gas and ions promote the hydroxylation of the electrode under tetra methyl ammonium hydroxide (TMAH) generated during corrosion, thereby changing the lattice structure and causing cracks, such that moisture is permeated through these cracks, thereby causing defects.

In order to solve the above-described problems, the inventor of the present disclosure has provided various embodiments of a display device having a structure capable of delaying or preventing moisture penetration in a portion of a non-display area between a display area and a bendable area.

For example, the disclosed display device includes a moisture-resistant structure positioned in the non-display area between the display area and bendable area. Adjacent grooves are formed in both the second planarization layer and touch buffer layer, creating concave and convex shapes that act as dams to delay or block moisture ingress. Additionally, a vertically protruding waterproof line passes through a dedicated through-hole in the planarization layer to contact the insulating layer, physically interrupting moisture pathways and preventing corrosion of underlying electrodes due to galvanic reactions.

In addition, some embodiments of the present disclosure provide a display device having a structure capable of delaying moisture from a portion of the planarization layer in the bendable area into a portion thereof in the display area in the portion of the non-display area between the display area and the bendable area, and having a waterproof line vertically protruding from a metal line to prevent the moisture penetration from a portion of the planarization layer in the bendable area into a portion thereof in the display area.

These structural features improve the reliability of the device by reducing the risk of crack formation and moisture intrusion at critical junctions, even under non-ideal manufacturing conditions. The use of bendable protective layers and a multi-layer sealing system further enhances mechanical durability and environmental resistance, supporting narrow bezel designs and improved production efficiency.

Technical benefits according to the present disclosure are not limited to the above-mentioned benefit. Other benefits and advantages according to the present disclosure that are not mentioned may be understood based on following descriptions, and may be more clearly understood based on implementations according to the present disclosure. Further, it will be easily understood that the purposes and advantages according to the present disclosure may be realized using means shown in the claims or combinations thereof.

An example display device according to an implementation of the present disclosure includes: a substrate including a display area, a non-display area, and a bendable area; an insulating layer disposed on the substrate; a first connection line disposed on the substrate and the insulating layer; a first planarization layer disposed on the insulating layer and the first connection line; a second connection line disposed on the first planarization layer; a second planarization layer disposed on the second connection line and the first planarization layer; a third planarization layer disposed on a portion of the second planarization layer; a touch buffer layer disposed on the second planarization layer and the third planarization layer; and a sealing layer disposed on the touch buffer layer, wherein between the display area and the bendable area, a first groove and a second groove are formed in each of the touch buffer layer and the second planarization layer so as to be recessed downwardly from an upper surface of each of the touch buffer layer and the second planarization layer, wherein the first and second grooves are adjacent to each other.

In this regard, between the display area and the bendable area, the second connection line is electrically connected to the first connection line via first and second through-holes vertically extending through the first planarization layer.

Further, in the portion of the non-display area between the display area and the bendable area, the second connection line includes a waterproof line vertically passing through a third through-hole vertically extending through the first planarization layer so as to contact the insulating layer.

Details of other implementations are included in the detailed description and drawings.

The solutions for achieving the purposes according to implementations of the present disclosure are not limited to the above-mentioned solutions, and other solutions not mentioned above will be clearly understood by those skilled in the art from following descriptions.

In the display device according to an implementation of the present disclosure, the plurality of grooves are defined in the planarization layer into which moisture is introduced in the portion of the non-display area between the display area and the bendable area, thereby delaying or preventing the penetration of moisture introduced through the planarization layer from a portion of the planarization layer in the bendable area into a portion thereof in the display area.

In addition, in the display device according to an implementation of the present disclosure, in the portion of the non-display area between the display area and the bendable area, the second connection line may be electrically connected to the first connection line via first and second through-holes vertically extending through the first planarization layer, and the waterproof line may vertically extend through a third through-hole vertically extending through the first planarization layer so as to contact the insulating layer. Thus, the penetration of moisture introduced through the planarization layer from a portion of the planarization layer in the bendable area into a portion thereof in the display area may be prevented.

In addition, in the display device according to the implementation of the present disclosure, in the portion of the non-display area between the display area and the bendable area, the plurality of grooves and the waterproof line may be formed in the planarization layer into which moisture is introduced, thereby preventing corrosion of the electrodes disposed in the planarization layer.

In addition, in the display device according to the implementation of the present disclosure, in the portion of the non-display area between the display area and the bendable area, the plurality of grooves and the waterproof line may be formed in the planarization layer into which moisture is introduced, thereby preventing the occurrence of cracks in the area between the display area and the bendable area.

In addition, in the display device according to the implementation of the present disclosure, in the portion of the non-display area between the display area and the bendable area, corrosion of the electrodes disposed in the planarization layer may be prevented and the occurrence of cracks in the area between the display area and the bendable area may be prevented, thereby improving the lifespan of the display device and realizing a long-life display device.

In addition, according to an implementation of the present disclosure, the moisture may be prevented from invading into the display device, thereby preventing the occurrence of defects even when the manufacturing process is not optimized, thereby improving the quality of the

In addition, according to an implementation of the present disclosure, preventing the occurrence of defects in the display device may allow the production energy to be reduced.

In addition, according to an implementation of the present disclosure, as the quality of the display device is improved, reliability thereof may be secured accordingly, and thus a narrow bezel may be implemented.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is a plan view illustrating a display device according to an implementation of the present disclosure.

FIG. 2 is a cross-sectional view illustrating a cross-section taken along a line A-A′ of FIG. 1 in a display device according to an implementation of the present disclosure;

FIG. 3 is an enlarged view of a portion A of FIG. 2 in a display device according to an implementation of the present disclosure.

FIG. 4 is an enlarged view of a portion B of FIG. 2 in a display device according to an implementation of the present disclosure.

FIG. 5 is a cross-sectional view of a display device according to an implementation of the present disclosure taken along a line B-B′ of FIG. 1.

FIG. 6 is a cross-sectional view illustrating a stacked form of a display device according to an implementation of the present disclosure.

### DETAILED DESCRIPTION

Advantages and features of the present disclosure, and a method of achieving the advantages and features will become apparent with reference to implementations described later in detail together with the accompanying drawings. However, the present disclosure is not limited to the implementations as disclosed under, but may be implemented in various different forms. Thus, these implementations are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various implementations are illustrated and described further below. It will be understood that the description herein is not intended to limit the claims to the specific implementations described. On the contrary, it is intended to cover alternatives, modifications, and equivalents as may be included within the spirit and scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular implementations only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers.

It will be understood that when an element or layer is referred to as being “connected to”, or “coupled to” another element or layer, it may be directly connected to, or coupled to the other element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present.

To further elaborate, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Further, as used herein, when a layer, film, area, plate, or the like is disposed “on” or “on top” of another layer, film, area, plate, or the like, the former may directly contact the latter or still another layer, film, area, plate, or the like may be disposed between the former and the latter. As used herein, when a layer, film, area, plate, or the like is directly disposed “on” or “on top” of another layer, film, area, plate, or the like, the former directly contacts the latter and still another layer, film, area, plate, or the like is not disposed between the former and the latter. Further, as used herein, when a layer, film, area, plate, or the like is disposed “beneath” or “under” another layer, film, area, plate, or the like, the former may directly contact the latter or still another layer, film, area, plate, or the like may be disposed between the former and the latter. As used herein, when a layer, film, area, plate, or the like is directly disposed “beneath” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain implementation may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or period. Thus, a first element, component, area, layer or section as described under could be termed a second element, component, area, layer or period, without departing from the spirit and scope of the present disclosure.

When an implementation may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various implementations of the present disclosure may be partially or entirely combined with each other, and may be technically associated with each other or operate with each other. The implementations may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “implementations,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating implementations.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B through another node unless a phrase ‘immediately transferred’ or ‘directly transferred’ is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

As used herein, the term “display device” may include, in a narrow sense, a display device including a liquid crystal module (LCM), an organic light-emitting diode (OLED) module, or a quantum dot (QD) module including a display panel and a driver for driving the display panel. Moreover, the display device may include, in a broad sense, a laptop computer, a television, a computer monitor, an automotive device or an equipment display for a vehicle, a set electronic device, a set device or a set device including a complete product or a final product including the LCM, the OLED module, or the QD module.

Therefore, the display device in accordance with the present disclosure may include, in the narrow sense, a display device itself including, for example, the LCM, the OLED module, QD module, etc., and may include, in a broad sense, the set device as an application product or an end-user device including a complete product or a final product including the LCM, the OLED module, or the QD module.

Moreover, in some cases, the LCM, OLED module, or QD module composed of the display panel and the driver may be expressed as “display device” in a narrow sense. The electronic device as a complete product including the LCM, OLED module or QD module may be expressed as “set” device” in a broad sense. For example, the display device in the narrow sense may include a display panel such as a liquid crystal panel, an organic light-emitting display panel, or a quantum dot display panel, and a source PCB as a controller for driving the display panel. The set device in the broad sense may include a display panel such as a liquid crystal panel, an organic light-emitting display panel, or a quantum dot display panel, a source PCB as a controller for driving the display panel, and a set PCB as a set controller that is electrically connected to the source PCB and controls the set device.

As used herein, the display panel may be of any type of the display panels such as a liquid crystal display panel, an organic light emitting diode (OLED) display panel, a quantum dot (QD) display panel, and an electroluminescent display panel, etc. The display panel used in the disclosure may be not limited to a specific display panel including a flexible substrate for the OLED display panel and an underlying back plate support structure and having a bendable bezel. Moreover, the display panel used in the display device according to an implementation of the present disclosure is not limited to a shape or a size of the display panel.

Hereinafter, implementations of the present disclosure will be described using the attached drawings. A scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

Hereinafter, a display device according to an implementation of the present disclosure will be described with reference to the drawings.

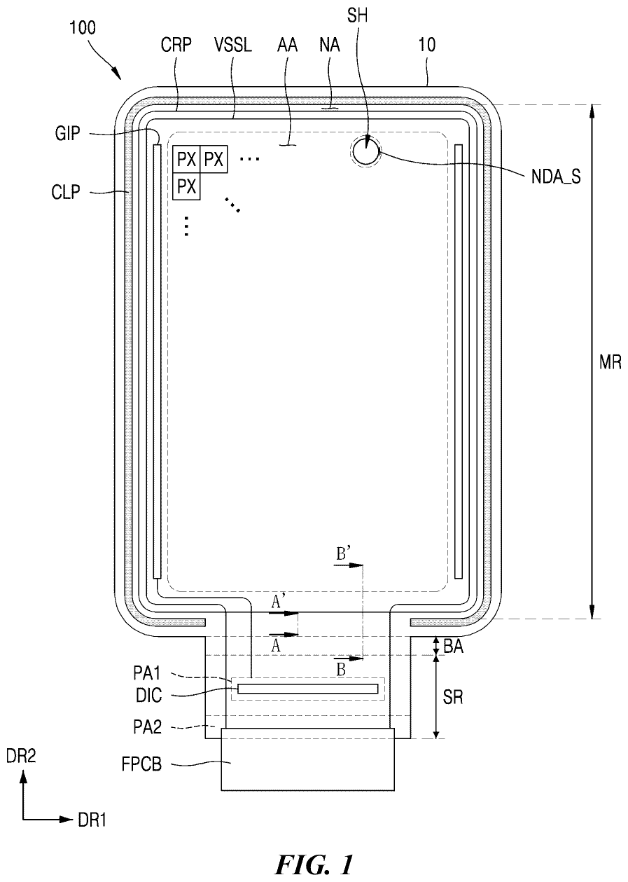

FIG. 1 is a plan view illustrating a display device according to an implementation of the present disclosure.

Referring to FIG. 1, a display device 100 according to an implementation of the present disclosure may include a substrate 10.

The substrate 10 may include a plurality of areas. The plurality of areas may include a main area MR, a bendable area BA, and a sub-area SR.

The main area MR may include a display area (Active Area) AA and a non-display area (Non-active Area) NA. The bendable area BA may be an area that is bent from the main area MR in a thickness direction. The sub-area SR may be an area connected to the bendable area BA and facing the main area MR

The display area AA may be an area in which an image is displayed. The non-display area NA may be an area other than the display area AA. Although not being illustrated, a pixel array may be formed in the display area AA.

The one or more non-display areas NA in which an image is not displayed may include a driving circuit area DIC and a clad area CLP serving as a dam and may be provided on one side of the display area AA. For example, the non-display area NA may be adjacent to one or more side surfaces of the display area AA.

The non-display area NA may surround a rectangular display area AA and may be located outside the display area AA. However, it should be understood that the shape of the display area AA and the arrangement of the non-display area NA adjacent to the display area AA are not specifically limited to the example display device 100 illustrated in FIG. 1. Each of the display area AA and the non-display area NA may have any shape. Non-limiting examples of the shape may include a pentagonal, hexagonal, circular, elliptical shape, etc., and implementations herein are not limited thereto.

A crack detection pattern CRP may be disposed in the non-display area NA in a form that surrounds three sides of the display area AA. The crack detection pattern CRP may be used to detect a state in which a crack occurs in the substrate 10.

A low-potential power line VSSL may be disposed between the crack detection pattern CRP and the display area AA so as to surround the three sides of the display area AA.

A gate driver GIP may be disposed in the non-display area NA and at both opposing side ends around the display area AA, respectively. The gate driver GIP supplies a gate signal (or a scan signal) to the display area AA.

The display area AA may include a second non-display area NA_S in which a camera area SH is disposed. A camera may be disposed inside the camera area SH.

The bendable area BA may be disposed between the main area MR and the sub-area SR, and may connect the main area MR and the sub-area SR to each other. A width of the bendable area BA in a first direction DR1 may be smaller than each of a width of the main area MR in the first direction DR1 and the width of the sub-area SR in the first direction DR1.

Although not shown, the display device 100 may further include a plurality of lines extending from the sub-area SR to the main area MR through the bendable area BA. The plurality of lines may include a first line to which a first voltage is applied, a second line to which a second voltage is applied, and a dummy line which is disposed between the first line and the second line and to which a third voltage is applied.

Although not shown, the display device 100 may further include a data driver DIC disposed in the sub-area SR, and each of the first line and the second line may be connected to the data driver DIC.

The display area AA may include a plurality of pixels PX. One pixel PX may include a plurality of sub-pixels. Each of the plurality of sub-pixels may include a light-emitting element. The light-emitting element may be an inorganic light-emitting element or an organic light-emitting element. However, implementations of the present disclosure are not limited thereto. The plurality of sub-pixels may emit light of colors such as red (R), green (G), blue (B), and white (W), respectively. The plurality of sub-pixels may be disposed in the display area AA. Each of the plurality of sub-pixels may include one or more transistors. At least one transistor and the light-emitting element may be connected to each other.

In addition, each of the pixel PX and the sub-pixel SP may be associated with a pixel circuit including one or more TFTs fabricated on the substrate 10 of the display device 100. Each of the pixel circuits may be electrically connected to a gate line and a data line to communicate with one or more driving circuits, for example, the gate driver GIP and the data driver DIC located in the non-display area NA of the display device 100.

The sub-area SR may include a first pad area PA1 and a second pad area PA2. The data driver DIC may be disposed in the first pad area PA1, and a flexible circuit board FPCB may be disposed in the second pad area PA2.

The one or more driving circuits may be implemented using TFTs disposed in the non-display area NA. For example, the gate driver GIP may be implemented using a plurality of TFTs on the substrate 10 of the display device 100. Non-limiting examples of the circuits that may be implemented using the TFT on the substrate 10 may include an inverter circuit, a multiplexer, an electro static discharge (ESD) circuit, etc. However, implementations of the present disclosure are not limited thereto.

Some of the driving circuits may be provided as an integrated circuit (IC) chip, and may be mounted in the non-display area NA of the display device 100 using a chip-on-glass (COG) or other similar schemes. In addition, the other driving circuits may be mounted on another substrate and may be coupled to a connection interface (pads/bumps, pins) disposed in the non-display area NA using the flexible circuit board FPCB, a chip-on-film (COF), a tape-carrier-package (TCP), or other suitable techniques.

In implementations herein, at least two different types of TFTs are used in a TFT substrate for display. The types of TFTs employed in a portion of the pixel circuit and a portion of the driving circuit may vary according to the requirements of the display.

For example, the pixel circuit may be implemented using TFT (oxide TFT) having an oxide active layer, and the driving circuit may be implemented using TFT (LTPS TFT) having a low temperature polycrystalline silicon active layer and TFT having an oxide active layer. Unlike the LTPS TFTs, the oxide TFTs do not suffer from the problem of the pixel-to-pixel variation of the threshold voltage Vth. The uniform threshold voltage Vth may also be obtained in an array of pixel circuits for display. The uniformity of the threshold voltages Vth of TFTs implementing the driving circuit will have less direct influence on the luminance uniformity of the pixels.

Using the drive circuits on the substrate to be implemented using LTPS TFTs, signals and data may be provided to the pixels at a higher clock than when all TFTs in the TFT panel are embodied as the oxide TFTs. Accordingly, a display capable of high-speed operation may be provided without stains such as mura. For example, the advantage of each of the oxide TFT and the LTPS TFT may be used in combination with the design of the TFT panel to select the oxide TFT and the LTPS TFT according to the advantage thereof.

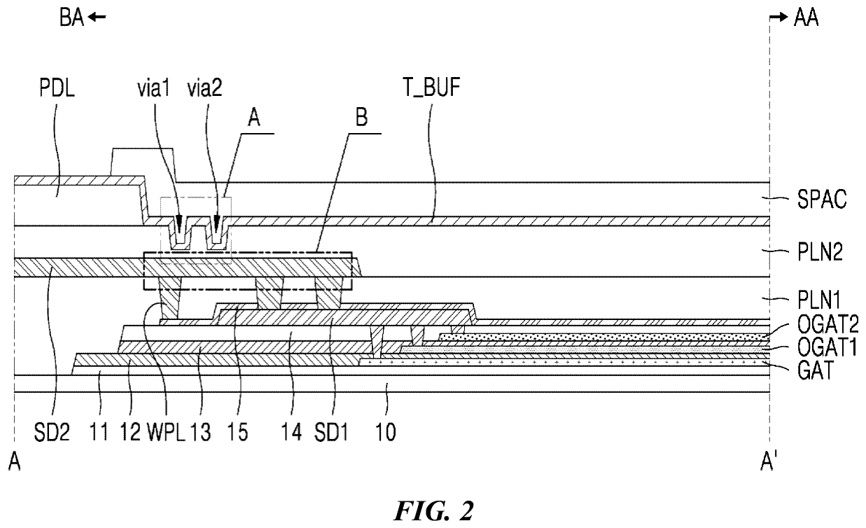

FIG. 2 is a cross-sectional view illustrating a cross-section taken along a line A-A′ of FIG. 1 in a display device according to an implementation of the present disclosure.

Referring to FIG. 2, the display device according to an implementation of the present disclosure may include a substrate 10, insulating layers 11 to 15, a first connection line SD1, a first planarization layer PLN1, a second connection line SD2, a second planarization layer PLN2, a third planarization layer PDL, a touch buffer layer T-BUF, and an sealing layer SPAC.

The substrate 10 may include a display area AA, a non-display area NA, and a bendable area BA. Although not shown, the substrate 10 may include, for example, a first polyimide layer, an middle layer thereon, and a second polyimide layer thereon.

In addition, the substrate 10 may include, for example, a first substrate and a second substrate. The first substrate and the second substrate may be made of at least one of polyimide, polyethersulfone, polyethylene terephthalate, and polycarbonate. However, implementations of the present disclosure are not limited thereto. When the substrate 10 is made of a plastic material, a manufacturing process of the display device may be performed in a state in which a support substrate made of glass is disposed under the substrate 10, and after the manufacturing process of the display device has been completed, the support substrate may be released. In addition, after the support substrate has been released, a back plate (or a plate) for supporting the substrate may be disposed under the substrate. When the substrate is made of a plastic material, moisture may penetrate the substrate and may be transmitted to the thin-film transistor or the light-emitting element layer, thereby deteriorating the performance of the display device. The display device according to an implementation of the present disclosure may be composed of two substrates, that is, a first substrate and a second substrate, which are made of a plastic material, in order to prevent the performance of the display device from being deteriorated due to the moisture permeation. In addition, forming the middle layer as an inorganic film between the first substrate and the second substrate may allow the moisture to be prevented from extending through the substrate, thereby improving the performance reliability of the product. The middle layer may be made of an inorganic material. For example, the middle layer may be composed of a single layer made of silicon nitride (SiNx) or silicon oxide (SiOx), or of multiple layers made thereof. However, implementations of the present disclosure are not limited thereto.

In the stacked structure of the display device according to an implementation of the present disclosure, the insulating layers 11 to 14 may be disposed on the substrate 10, the first connection line SD1 may be disposed on the substrate 10 and the insulating layers 11 to 14, the first planarization layer PLN1 may be disposed on the insulating layers 11 to 14 and the first connection lines SD1, the second connection line SD2 may be disposed on the first planarization layer PLN1, the second planarization layer PLN2 may be disposed on the second connection line SD2 and the first planarization layer PLN1, the third planarization layer PDL may be disposed on a portion of the second planarization layer PLN2, the touch buffer layer T-BUF may be disposed on the second planarization layer PLN2 and the third planarization layer PLN3, and the sealing layer SPAC may be disposed on the touch buffer layer T-BUF.

Between the display area AA and the bendable area BA, a first groove via1 and a second groove via2 recessed downwardly from an upper surface may be formed in the touch buffer layer T-BUF and the second planarization layer PLN2 and may be adjacent to each other.

In this case, the first groove via1 of the touch buffer layer T-BUF may correspond to and overlap the first groove via1 of the second planarization layer PLN2, and the second groove via2 of the touch buffer layer T-BUF may correspond to and overlap the second groove via2 of the second planarization layer PLN2.

Each of the touch buffer layer T-BUF and the second planarization layer PLN2 may have a concave shape and a convex shape as the first groove via1 and the second groove via2 recessed downwardly from the upper surface are formed in each of the touch buffer layer T-BUF and the second planarization layer PLN2. In this case, the convex shape may be positioned between the concave shapes and may serve as a dam DAM. Accordingly, the penetration of moisture flowing into the second planarization layer PLN2 may be delayed due to the plurality of concave shapes, and may be blocked or prevented by the convex shape serving as the dam.

Between the display area AA and the bendable area BA, the second connection line SD2 may be electrically connected to the first connection line SD1 via first and second through-holes extending through the first planarization layer PLN1.

The second connection line SD2 may include a waterproof line WPL disposed between the display area AA and the bendable area BA and passing through a third through-hole vertically extending through the first planarization layer PLN1 so as to contact the fifth insulating layer 15.

Since the waterproof line WPL extends through the first planarization layer PLN1 through which moisture is introduced, the waterproof line WPL primarily blocks the moisture introduced into the first planarization layer PLN1. Accordingly, corrosion of the second connection line SD2 passing through the first and second through-holes of the first planarization layer PLN1 and electrically connected to the first connection line SD1 may be prevented.

In one implementation, the waterproof line WPL is integrally formed with the second connection line. That is, the waterproof line may protrude downwardly from the second connection line and be formed in the same layer. For example, since the waterproof line WPL is included as part of the second connection line, it may be patterned from the same metal film deposition and etching process used to form the second connection line SD2. Accordingly, the waterproof line WPL and the second connection line SD2 may both be made of one or more materials selected from titanium (Ti), molybdenum (Mo), copper (Cu), aluminum (Al), silver (Ag), chromium (Cr), gold (Au), neodymium (Nd), nickel (Ni), or tungsten (W).

The insulating layers 11 to 15 may include a first insulating layer 11 on the substrate 10, a first data line GAT on the first insulating layer 11, a second insulating layer 12 on the first insulating layer 11 and the first data line GAT, a second data line OGAT1 on the second insulating layer 12, a third insulating layer 13 on the second insulating layer 12 and the second data line OGAT, a third data line OGAT2 on the third insulating layer 13, a fourth insulating layer 14 on the third insulating layer 13 and the third data line OGAT2, the first connection line SD1 on the fourth insulating layer 14, and a fifth insulating layer 15 on the fourth insulating layer 14 and the first connection line SD1.

Between the display area AA and the bendable area BA, the first connection line SD1 may be electrically connected to the third data line OGAT2 via a through-hole vertically extending through the fourth insulating layer 14, may be electrically connected to the second data line OGAT1 via a through-hole vertically extending through the fourth insulating layer 14 and the third insulating layer 13, and may be electrically connected to the first data line GAT via a through-hole vertically extending through the fourth insulating layer 14, the third insulating layer 13, and the second insulating layer 12.

Each of the first connection line SD1 and the second connection line SD2 may be made of one or more materials among titanium (Ti), molybdenum (Mo), copper (Cu), aluminum (Al), silver (Ag), chromium (Cr), gold (Au), neodymium (Nd), nickel (Ni), tungsten (W), and gold (Au). However, implementations of the present disclosure are not limited thereto.

Each of the insulating layers 11 to 15 may include an inorganic material. For example, each of the first insulating layer 11 to the fifth insulating layer 15 may include an inorganic insulating material such as silicon oxide, silicon nitride, silicon oxynitride, hafnium oxide, aluminum oxide, titanium oxide, tantalum oxide, zinc oxide, or the like.

Each of the first planarization layer PLN1 to the third planarization layer PLN 3 may include an organic material. For example, each of the first planarization layer PLN1 to the third planarization layer PLN3 may include an organic insulating material such as polyacrylates resin, epoxy resin, phenolic resin, polyamides resin, polyimides resin, unsaturated polyesters resin, polyphenylenethers resin, polyphenylenesulfides resin, or benzocyclobutene (BCB).

Each of the first to third data lines GAT to OGAT2 may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu).

The sealing layer SPAC may include an insulating organic material. The insulating organic material may include one or more of BCB (BenzoCycloButene), acrylic resin, epoxy resin, phenolic resin, polyamide resin, or polyimide resin.

Although not shown in the drawings, the lines extending from the display area AA to the non-display area NA may include a data line for transmitting a data voltage signal to each pixel, a gate driving line for transmitting a signal to the gate driver GIP, a high potential power line for transmitting a driving voltage, a low potential power line VSSL, and a sensing signal line for transmitting a sensing signal.

These lines may be electrically connected to the data driver DIC and the flexible circuit board FPCB. The data driver DIC may be spaced apart from the flexible circuit board FPCB by a predetermined spacing.

The non-display area NA may include the clad area CLP in which a dam defining a position of an encapsulation layer for protecting the light-emitting elements of the display area AA is disposed.

The clad area CLP may be an area in which the gate driver GIP and the pixel PX of the display area AA are sealed with a dam. Although not illustrated, the clad area CLP may include, for example, a plurality of dams such as a first dam and a second dam. The first dam may be composed of a stack of a first layer and a second layer, in which the first layer may be made of the same material as and may be formed in the same process as a material and a process of the planarization layer, and the second layer may be made of the same material as and may be formed in the same process as a material and a process of the bank. The second dam may be composed of a stack of a first layer, a second layer, and a third layer in which the first layer may be made of the same material as and may be formed in the same process as a material and a process of the planarization layer, the second layer may be made of the same material as and may be formed in the same process as a material and a process of the bank, and the third layer may be made of the same material as and may be formed in the same process as a material and a process of a spacer SP. However, implementations of the present disclosure are not limited thereto. The first dam and the second dam may have a first height and a second height, respectively, and may surround the display area AA. The second height may be greater than the first height.

Although not shown, a plurality of partition walls may be disposed in the bendable area BA. However, implementations of the present disclosure are not limited thereto. The bendable area BA may include an area in which a partition wall is disposed, and a bendable protective layer may be disposed to overlap the partition wall. The bendable protective layer may include a polymer material to prevent moisture permeation into the bendable area BA. The bendable protective layer may be disposed outwardly of the display panel in the bendable area BA. The bendable protective layer improves deformation of the substrate 10 in the bendable area BA and allows the substrate 10 to be bent at a constant curvature. The bendable protective layer may be made of a resin to compensate for weakening of rigidity due to bending of the substrate 10 in the bendable area BA. In addition, the bendable protective layer may be made of a polymer such as polyimide (PI) or polyethylene terephthalate (PET). The bendable protective layer may have a modulus of about 1 to about 10 GPa when the bendable protective layer is embodied as a polymer film. However, implementations of the present disclosure are not limited thereto. The bendable protective layer may include resin, and may include an ultraviolet (UV) curable acrylic resin. However, implementations of the present disclosure are not limited thereto. The bendable protective layer may be made of a cured product of a resin. In this case, the resin may be coated and then may be subjected to a curing process. When the ultraviolet-curable resin is used as the resin, the ultraviolet curing may be performed thereon. The bendable protective layer may include, for example, a micro coating layer. The micro coating layer MCL may be referred to as a micro cover layer (MCL).

In one example, although not shown, a buffer layer including a single layer made of silicon nitride (SiNx) or silicon oxide (SiOx) or multiple layers made thereof may be disposed on one surface of the substrate 10 and in a combination of the display area AA and the non-display area NA. The buffer layer may improve adhesion between layers formed on the buffer layer and the substrate 10, and may serve to block various kinds of defect factors such as alkali components leaked from the substrate 10. In addition, the buffer layer may delay diffusion of moisture or oxygen invading through the substrate 10. The buffer layer may be omitted based on the type and material of the substrate, the structure and type of the thin-film transistor, etc.

The transistors of the display area AA may include a switching transistor or a driving transistor for driving the sub-pixel. A light blocking layer may be disposed under the driving transistor. The light blocking layer may be connected to a drain electrode DE of the driving transistor DT. The light blocking layer blocks light directed to the semiconductor layer SCL of the driving transistor DRT, and is connected to the drain electrode DE to prevent a phenomenon in which a drain current rapidly increases due to accumulation of parasitic carriers in the semiconductor layer or a change in a threshold voltage due to such a phenomenon.

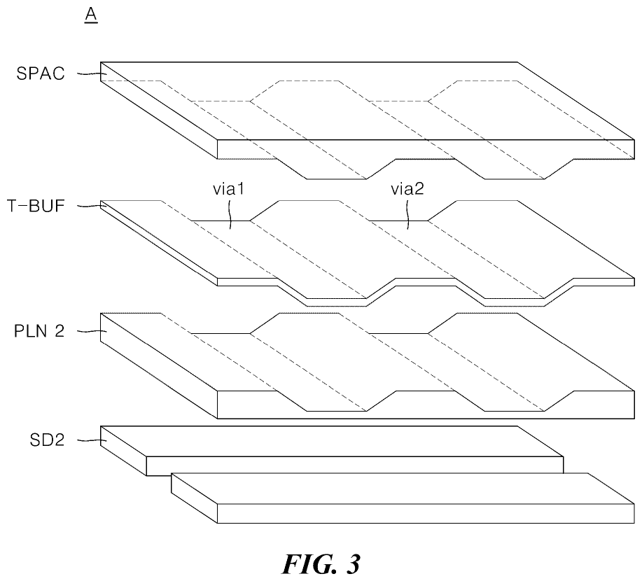

FIG. 3 is an enlarged view of a portion A of FIG. 2 in a display device according to an implementation of the present disclosure.

Referring to FIG. 3, in the portion A of FIG. 2 in the display device according to an implementation of the present disclosure, the second planarization layer PLN2 may be disposed on the second connection line SD2, the touch buffer layer T-BUF may be disposed on the second planarization layer PLN2, and the sealing layer SPAC may be disposed on the touch buffer layer T-BUF.

The second planarization layer PLN2 may be made of an organic insulating layer such as polyacrylate and polyimide, and thus, may reduce a step caused due to the lines and the contact holes formed thereunder.

In this regard, each of the second planarization layer PLN2 and the touch buffer layer T-BUF have the first and second grooves via1 and via2 recessed downwardly from the upper surface and adjacent to each other.

The touch buffer layer T-BUF may include an inorganic material, and may be etched downwardly from the upper surface thereof in an etching process to form the first groove via1 and the second groove via2 therein.

In the touch buffer layer T-BUF, each of the first groove via1 and the second groove via2 may have a concave shape, and a convex shape may be formed between the first groove via1 and the second groove via2.

The first groove via1 and the second groove via2 may also be formed in the second planarization layer PLN2 so as to correspond to and overlap the first groove via1 and the second groove via2 defined in the touch buffer layer T-BUF, respectively.

In the second planarization layer PLN2, each of the first groove via1 and the second groove via2 may have a concave shape, and a convex shape may be formed between the first groove via1 and the second groove via2. In this case, the convex shape between the first groove via1 and the second groove via2 may serve as a dam DAM. Accordingly, the first groove via1, the second groove via2, and the convex shape may block the moisture invading into the second planarization layer PLN2 or block the moisture penetration path.

The sealing layer SPAC may protect the display device 100 from external moisture, oxygen, or foreign substances. For example, the sealing layer SPAC may block penetration of oxygen and moisture from the outside to prevent oxidation of the light-emitting material and the electrode material. The sealing layer SPAC may be made of a transparent material so that light emitted from the light-emitting element transmits therethrough. The sealing layer SPAC may be disposed on the light-emitting element in the display area AA. The sealing layer SPAC may include a plurality of sealing layers for blocking penetration of moisture or oxygen. However, implementations of the present disclosure are not limited thereto. The plurality of sealing layers may be sequentially stacked. However, implementations of the present disclosure are not limited thereto. The plurality of sealing layers SPAC may be made of at least one inorganic material selected from silicon nitride (SiNx), silicon oxide (SiOx), or aluminum oxide (AlyOz). However, implementations of the present disclosure are not limited thereto.

The touch buffer layer T-BUF may be made of at least one inorganic material selected from silicon nitride (SiNx), silicon oxide (SiOx), or aluminum oxide (AlyOz). However, implementations of the present disclosure are not limited thereto.

Although not shown, a touch operation may be executed using a plurality of sensing electrodes and a plurality of driving electrodes disposed in the display area AA. The sensing electrode includes a plurality of sub-sensing electrodes extending along the first direction DR1 and arranged so as to be spaced from each other by a predetermined spacing along the second direction DR2. Each of the plurality of sensing electrodes TE may continuously extend without being broken in the first direction DR1. The first direction DR1 and the second direction DR2 may intersect each other. For example, the first direction DR1 and the second direction DR2 may be orthogonal to each other.

The plurality of driving electrodes includes a plurality of sub-driving electrodes extending along the second direction DR2 and arranged so as to be spaced from each other by a predetermined spacing along the first direction DR1. The plurality of sub-driving electrodes TE may be electrically connected to each other in the second direction DR2.

When the plurality of sub-sensing electrodes and the plurality of sub-driving electrodes are formed in the same layer, the plurality of sub-driving electrodes may be electrically connected to each other through a bridge pattern. The plurality of sub-sensing electrodes and the plurality of sub-driving electrodes may have a metal mesh structure. In addition, the plurality of sub-sensing electrodes may be electrically connected to each other through a bridge pattern, and each of the plurality of sub-driving electrodes may continuously extend without being broken.

Although not shown, the touch buffer layer T-BUF may include a touch insulating layer, and may be disposed so as to extend toward the bendable area BA to extend an external moisture penetration blocking path to reduce the moisture penetration.

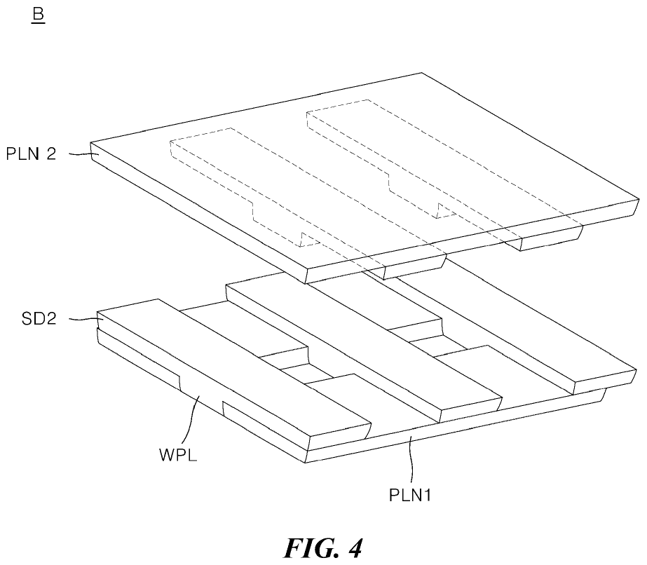

FIG. 4 is an enlarged view of a portion B of FIG. 2 in a display device according to an implementation of the present disclosure.

Referring to FIG. 4, in the display device according to the implementation of the present disclosure, in the portion B of FIG. 2, the second connection line SD2 may be disposed on the first planarization layer PLN1, and the second planarization layer PLN2 may be disposed on the second connection line SD2.

Each of the first planarization layer PLN1 and the second planarization layer PLN2 may be made of an organic insulating layer such as polyacrylate and polyimide. However, implementations of the present disclosure are not limited thereto.

In this case, the second connection line SD2 may include two connection lines extending in a downward direction through the plurality of through-holes extending through the first planarization layer PLN1 and the fifth insulating layer 15 so as to contact the first connection line SD1, and may include the waterproof line WPL extending in a downward direction through the third through-holes extending through the first planarization layer PLN1 so as to contact the fifth insulating layer 15.

Accordingly, the waterproof line WPL of the second connection line SD2 may block the moisture penetrating into the first planarization layer PLN1, thereby preventing moisture from flowing toward the two connection lines.

In addition, the waterproof line WPL of the second connection line SD2 may prevent the moisture penetration into the two connection lines, thereby preventing corrosion caused by the moisture of the two connection lines extending in the downward direction through the plurality of through-holes.

Each of the first planarization layer PLN1 and the second planarization layer PLN2 may be made of at least one of organic insulating materials such as benzoCycloButene (BCB), acryl resin, epoxy resin, phenolic resin, polyamide resin, or polyimide resin. However, implementations of the present disclosure are not limited thereto.

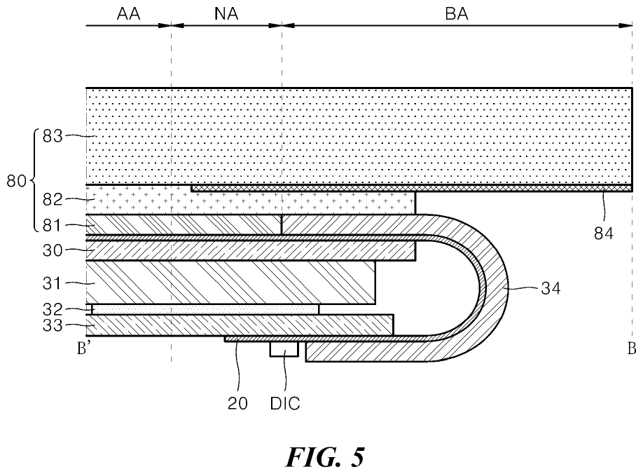

FIG. 5 is a cross-sectional view of a display device according to an implementation of the present disclosure taken along a line B-B′ of FIG. 1.

Referring to FIG. 5, an optical adjustment layer 81 may be disposed on a display panel 20, an adhesive layer 82 may be disposed on the optical adjustment layer 81, and a cover member 83 may be disposed on the adhesive layer 82. FIG. 5 schematically illustrates a cross-sectional view of an area in which the display panel 20 is bent in the display device 100.

The optical adjustment layer 81 may include a polarizing film, and may be referred to as a polarizing layer POL. Implementations of the present disclosure are not limited thereto. The optical adjustment layer 81 may prevent or reduce light generated from an external light source from entering the display panel 20 and affecting the light-emitting element LD.

The cover member 83 may be a member for protecting the display panel 20. The adhesive layer 82 may be disposed between the optical adjustment layer 81 and the cover member 83. The cover member 83 may be attached to the display panel 20 via the adhesive layer 82. The adhesive layer 82 may include an OCA (Optically clear adhesive), an OCR (Optically clear resin), a PSA (Pressure sensitive adhesive), or the like. However, implementations of the present disclosure are not limited thereto.

The display device 100 may further include first and second back plates 30 and 33 disposed on a rear surface of the display panel 20 in the display area AA. The first back plate 30 and the second back plate 33 supporting the display panel 20 may be attached to a lower surface of the display panel 20. The first back plate 30 may be disposed in the display area AA, and the second back plate 33 may be spaced apart from the first back plate 30 by a predetermined distance and may be disposed in a pad line area and an area of the data driver DIC and the flexible circuit board FPCB.

Each of the first back plate 30 and the second back plate 33 may include at least one of polyimide (PI), polyethylene naphthalate (PEN), polyethylene terephthalate (PET), polymers, and combinations of the polymers.

The display panel 20 is bent in the area where the first back plate 30 and the second back plate 33 are spaced apart from each other, so that a lower surface of the first back plate 30 and a lower surface of the second back plate 33 may face each other.

The display panel 20 may include a first flat portion, a second flat portion facing the first flat portion, and a curved portion that extends from the first flat portion and is bent in a rear direction, and is positioned between the first flat portion and the second flat portion. The first and second back plates 30 and 33 may be positioned on the rear surfaces of the first and second flat portions, respectively.

The display device 100 may further include a fixing member 31 disposed on the rear surface of the first back plate 30, and an adhesive member 32 disposed between the fixing member 31 and the second back plate 33.

The fixing member 31 may be disposed under the first back plate 30. The fixing member 31 may include an adhesive and a heat dissipation sheet, and may include a metal layer capable of reflecting external light therefrom. However, implementations of the present disclosure are not limited thereto.

The fixing member 31 may be made of a metal material, or may include a composite heat dissipation sheet having a heat dissipation function, a grounding function, and a function of protecting the rear surface.

The adhesive member 32 for connecting the fixing member 31 and the second back plate 33 to each other may be disposed under the fixing member 31. The adhesive member 32 may be a double-sided tape, a double-sided foam adhesive tape, or a double-sided foam adhesive pad.

The display device 100 may further include a bendable protective layer 34 disposed on an outer surface of the bent portion of the display panel 20 in the bendable area BA. The bendable protective layer 34 may be disposed in the bendable area BA of the display panel 20. The bendable protective layer 34 may include a micro coating layer made of a resin-based material. The bendable protective layer 34 may include a polymer material to prevent moisture permeation into the bendable area BA.

A cover window 80 may be disposed on the display panel 20. The cover window 80 may include the optical adjustment layer 81, the adhesive layer 82, and the cover member 83.

An end of the cover member 83 may be disposed outwardly beyond an outer end of the bent portion of the display panel 20. The cover member 83 may include a black ink 84 applied to a portion thereof corresponding to the non-display area NA in order to prevent light leakage of the non-display area NA of the display panel 20. The black ink 84 may be, for example, a Black Matrix (BM) including a black material.

The data driver DIC as a driving circuit may be disposed on a distal end of a rear surface of the bent portion of the display panel 20.

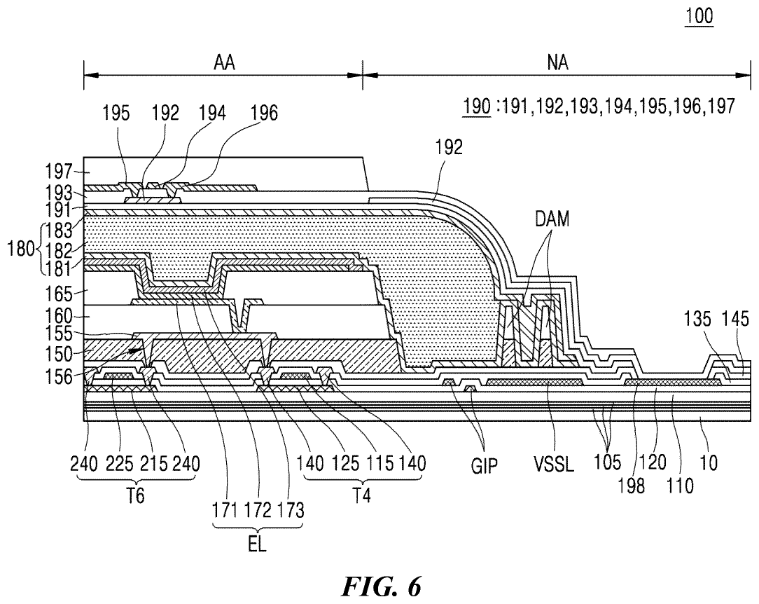

FIG. 6 is a cross-sectional view illustrating a stacked form of a display device according to an implementation of the present disclosure.

Referring to FIG. 6, in the display device 100 according to an implementation of the present disclosure, a light-emission transistor T4 for driving the light-emitting element EL may be disposed on the display area AA of the substrate 10 including the display area AA and the non-display area NA. The light-emission transistor T4 may include a fourth semiconductor layer 115, a fourth gate electrode 125, and source and drain electrodes 140 as a first electrode and a second electrode.

In this regard, each of the source and drain electrodes 140 of the light-emission transistor T4 may be made of the same material as that of the first connection line SD1 shown in FIG. 2 and may be formed in the same layer as the layer of the first connection line SD1.

In addition, in the display device 10 according to an implementation of the present disclosure, a reset transistor T6 for resetting an anode electrode of the light-emitting element EL may be disposed in the display area AA and on the substrate 10. The reset transistor T6 may include a sixth semiconductor layer 215, a sixth gate electrode 225, and source and drain electrodes 240 as a first electrode and a second electrode thereof.

In this regard, each of the source and drain electrodes 240 of the reset transistor T6 may be made of the same material as the first connection line SD1 shown in FIG. 2 and may be formed in the same layer as the layer of the first connection line SD1.

For convenience of description, only the light-emission transistor T4 and the reset transistor T6 among various thin-film transistors that may be included in the display device 100 are illustrated. However, other thin-film transistors such as a switching transistor may also be included in the display device 100. In addition, although an example in which the thin-film transistor TFT is embodied as having a coplanar structure has been described in the present disclosure, the thin-film transistor may be implemented in another structure such as a staggered structure. However, implementations of the present disclosure are not limited thereto.

The light-emission transistor T4 may receive a high potential driving voltage EVDD in response to a light-emission control signal EM supplied to the fourth gate electrode 125 of the light-emission transistor T4 to control the current supplied to the light-emitting element EL, thereby adjusting the amount of light emitted from the light-emitting element EL, and may supply a constant current until a data signal of a next frame is supplied thereto, based on a voltage charged in a storage capacitor (not shown), so that the light-emitting element EL may maintain light-emission thereof. A high potential voltage supply line extends in parallel with the data line.

The reset transistor T6 may receive a reset voltage signal Var in response to the emission control signal EM supplied to the sixth gate electrode 225 of the reset transistor T6 and transmit the reset voltage signal Var to the anode electrode N5 as the first electrode of the light-emitting element EL, so that the anode electrode of the light-emitting element EL may be reset.

As illustrated in FIG. 6, the light-emission transistor T4 may include the fourth semiconductor layer 115 disposed on the first insulating layer 110, the fourth gate electrode 125 overlapping the fourth semiconductor layer 115 while the second insulating layer 120 is interposed therebetween, and the source and drain electrodes 140 formed on the third insulating layer 135 and in contact with the fourth semiconductor layer 115. In the light-emission transistor T4, when the first electrode thereof is a source electrode, the second electrode thereof may be a drain electrode. On the contrary, when the first electrode thereof is a drain electrode, the second electrode thereof may be a source electrode. The light-emission transistor T4 may include a P-type (P-MOSFET) thin-film transistor TFT and a low temperature polycrystalline silicon (LTPS) thin-film transistor TFT.

As illustrated in FIG. 6, the reset transistor T6 may include the sixth semiconductor layer 215 disposed on the first insulating layer 110, the sixth gate electrode 225 overlapping the sixth semiconductor layer 215 while the second insulating layer 120 is interposed therebetween, and the source and drain electrodes 240 formed on the third insulating layer 135 and in contact with the sixth semiconductor layer 215. In the reset transistor T6, when the first electrode thereof is a source electrode, the second electrode thereof may be a drain electrode. On the contrary, when the first electrode thereof is a drain electrode, the second electrode thereof may be a source electrode. The reset transistor T6 may include a P-type (P-MOSFET) thin-film transistor TFT and a low temperature polycrystalline silicon (LTPS) thin-film transistor TFT.

Each of the fourth semiconductor layer 115 and the sixth semiconductor layer 215 may be an area in which a channel is formed when the corresponding thin-film transistor TFT operates. Each of the fourth semiconductor layer 115 and the sixth semiconductor layer 215 may be made of an oxide semiconductor, or may be made of various organic semiconductors such as amorphous silicon (a-Si), polycrystalline silicon (poly-Si), or pentacene. However, implementations of the present disclosure are not limited thereto. The fourth semiconductor layer 115 and the sixth semiconductor layer 215 may be formed on the first insulating layer 110. Each of the fourth semiconductor layer 115 and the sixth semiconductor layer 215 may include a channel area CH, a source area SR, and a drain area DR. Each channel area CH thereof may overlap each of the fourth gate electrode 125 and the sixth gate electrode 225 while the first insulating layer 110 is interposed therebetween to form each of the channel area CH between the source and drain electrodes 140 and the channel area CH between the source and drain electrodes 240. Each source area SR is electrically connected to each of the source electrodes 140 and 240 via each contact hole vertically extending through the second insulating layer 120 and the third insulating layer 135. Each drain area DR may be electrically connected to each of the drain electrodes 140 and 240 via each contact hole vertically extending through the second insulating layer 120 and the third insulating layer 135. A buffer layer 105 and the first insulating layer 110 may be disposed between the fourth semiconductor layer 115 and the sixth semiconductor layer 215 and the substrate 10. The buffer layer 105 may delay the diffusion of moisture and/or oxygen flowing through the substrate 10. The first insulating layer 110 may protect the fourth semiconductor layer 115 and the sixth semiconductor layer 215, and may block various kinds of defects introduced from the substrate 10.

The uppermost layer of the buffer layer 105 in contact with the first insulating layer 110 may be made of a material having different etching characteristics from those of each of the remaining layers of the buffer layer 105, the first insulating layer 110, the second insulating layer 120 and the third insulating layer 135. The uppermost layer of the buffer layer 105 contacting the first insulating layer 110 may be made of one of silicon nitride (SiNₓ) and silicon oxide (SiOₓ). Each of the remaining layers of the buffer layer 105, the first insulating layer 110, the second insulating layer 120, and the third insulating layer 135 may be made of the other of silicon nitride (SiNₓ) and silicon oxide (SiOₓ). For example, the uppermost layer of the buffer layer 105 in contact with the first insulating layer 110 may be made of silicon nitride (SiNₓ), while each of the remaining layers of the buffer layer 105, the first insulating layer 110, the second insulating layer 120, and the third insulating layer 135 may be made of silicon oxide (SiOₓ). The present disclosure is not limited thereto.

Each of the fourth gate electrode 125 and the sixth gate electrode 225 may be formed on the second insulating layer 120, and may overlap the channel area of each of the fourth semiconductor layer 115 and the sixth semiconductor layer 215 while the second insulating layer 120 is interposed therebetween. Each of the fourth gate electrode 125 and the sixth gate electrode 225 may be made of a first conductive material and may be embodied as a single layer or multi-layers made of magnesium (Mg), molybdenum (Mo), aluminum (Al), chromium (Cr), gold (Au), titanium (Ti), nickel (Ni), neodymium (Nd), copper (Cu), or an alloy thereof. The present disclosure is not limited thereto.

Each of the source electrodes 140 and 240 may be connected to a portion of each of the respective source areas of the fourth semiconductor layer 115 and the sixth semiconductor layer 215 exposed through each of the contact holes extending through the second insulating layer 120 and the third insulating layer 135. Each of the drain electrodes 140 and 240 may be opposite to each of the source electrodes 140 and 240, and may be connected to each of the respective drain areas of the fourth semiconductor layer 115 and the sixth semiconductor layer 215 via each of the contact holes extending through the second insulating layer 120 and the third insulating layer 135. Each of the source and drain electrodes 140 and 240 may be made of a second conductive material and may be embodied as a single layer or multi-layers made of molybdenum (Mo), aluminum (Al), chromium (Cr), gold (Au), titanium (Ti), nickel (Ni), neodymium (Nd), copper (Cu), or an alloy thereof. The present disclosure is not limited thereto.

A connection electrode 155 may be disposed between a first middle layer 150 and a second middle layer 160. The connection electrode 155 may be connected to each of the drain electrodes 140 and 240 via each of connection electrode contact holes 156 extending through a protective film 145 and the first middle layer 150. The connection electrode 155 may be made of a material having low resistivity and identical to or similar to that of each of the drain electrodes 140 and 240. The present disclosure is not limited thereto.

In this regard, the connection electrode 155 may be made of the same material as that of the second connection line SD2 illustrated in FIG. 2 and may be disposed in the same layer as the layer of the second connection line SD2.

In addition, the first middle layer 150 may correspond to the first planarization layer PLN1 illustrated in FIG. 2, and the second middle layer 160 may correspond to the second planarization layer PLN2 illustrated in FIG. 2.

Referring to FIG. 6, the light-emitting element EL including a light-emitting layer 172 may be disposed on the second middle layer 160 and a bank layer 165. The light-emitting element EL may include an organic electroluminescence diode OLED. In the light-emitting element EL, the first electrode thereof may be the anode electrode, and a second electrode thereof may be a cathode electrode.

The light-emitting element 170 may include the anode electrode 171, the at least one light-emitting layer 172 formed on the anode electrode 171, and the cathode electrode 173 formed on the light-emitting layer 172.

The anode electrode 171 may be electrically connected to an exposed portion of the connection electrode 155 disposed on the first middle layer 150 and facing the second middle layer 160 via a contact hole vertically extending through the second middle layer 160.

The anode electrode 171 of each pixel is not covered with the bank layer 165. The bank layer 165 may be made of an opaque material (e.g., black) to prevent light interference between adjacent pixels. In this case, the bank layer 165 may include a light-shielding material including at least one of color pigment, organic black, and carbon black. The present disclosure is not limited thereto.

Referring to FIG. 6, the at least one light-emitting layer 172 may be formed on a portion of the anode electrode 171 corresponding to a light-emitting area defined by the bank layer 165. The at least one light-emitting layer 172 may include a hole transport layer, a hole injection layer, a hole blocking layer, a light-emitting layer 172, an electron injection layer, an electron blocking layer, and an electron transport layer disposed on the anode electrode 171. A stacking order of the hole transport layer, the hole injection layer, the hole blocking layer, the light-emitting layer 172, the electron injection layer, the electron blocking layer, and the electron transport layer may be based on a light-emitting direction. In addition, the light-emitting layer 172 may include first and second light-emitting stacks facing each other while a charge generating layer is interposed therebetween. In this case, the light-emitting layer 172 of one of the first and second light-emitting stacks may generate blue light, while the light-emitting layer 172 of the other of the first and second light-emitting stacks may generate yellow-green light, so that white light may be generated from a combination of the first and second light-emitting stacks. The white light generated from the combination of the first and second light-emitting stacks may be incident on a color filter positioned above or below the light-emitting layer 172, such that a color image may be realized. In another example, each light-emitting layer 172 may generate each color light corresponding to each pixel without a separate color filter such that a color image may be rendered. For example, the light-emitting layer 172 of a red (R) pixel emits red light, the light-emitting layer 172 of a green (G) pixel emits green light, and the light-emitting layer 172 of a blue (B) pixel emits blue light.

Referring to FIG. 6, the cathode electrode 173 may be formed to face the anode electrode 171 while the light-emitting layer 172 is disposed therebetween, and may receive the high-potential driving voltage EVDD.

An encapsulation layer 180 may block penetration of external moisture or oxygen into the light-emitting element EL that is vulnerable to external moisture or oxygen. To this end, the encapsulation layer 180 may include at least one inorganic encapsulation layer and at least one organic encapsulation layer. The present disclosure is not limited thereto. In the present disclosure, a structure of the encapsulation layer 180 in which a first encapsulation layer 181, a second encapsulation layer 182, and a third encapsulation layer 183 are sequentially stacked is described by way of example.

The first encapsulation layer 181 is formed on the substrate 10 on which the cathode electrode 173 has been formed. The third encapsulation layer 183 is formed on the substrate 10 on which the second encapsulation layer 182 has been formed. The third encapsulation layer 183 and the first encapsulation layer 181 may surround a top face, a bottom face and a side face of the second encapsulation layer 182. The first encapsulation layer 181 and the third encapsulation layer 183 may minimize or prevent penetration of external moisture or oxygen into the light-emitting element EL. Each of the first encapsulation layer 181 and the third encapsulation layer 183 may be made of an inorganic insulating material that may be deposited at a low temperature, such as silicon nitride (SiNₓ), silicon oxide (SiOₓ), silicon oxynitride (SiON), or aluminum oxide (Al₂O₃). Each of the first encapsulation layer 181 and the third encapsulation layer 183 is deposited in a low temperature atmosphere. Thus, during a deposition process of the first encapsulation layer 181 and the third encapsulation layer 183, the light-emitting element EL which is vulnerable to a high-temperature atmosphere may be prevented from being damaged.

The second encapsulation layer 182 serves as a shock-absorbing layer to relieve a stress between layers due to bending of the display device 10, and may planarize a step between layers. The second encapsulation layer 182 may be made of a non-photosensitive organic insulating material such as acryl resin, epoxy resin, phenolic resin, polyamide resin, polyimide resin, polyethylene or silicon oxycarbon (SiOC) or a photosensitive organic insulating material such as photoacryl. The present disclosure is not limited thereto. When the second encapsulation layer 182 is formed using an inkjet method, a dam DAM may be disposed to prevent the second encapsulation layer 182 in a liquid state from spreading to an edge of the substrate 10. The dam DAM may be closer to the edge of the substrate 10 than the second encapsulation layer 182 may be. The dam DAM may prevent the second encapsulation layer 182 in the liquid state from spreading to a pad area where a conductive pad disposed at the outermost side of the substrate 10 is disposed.

The dam DAM is designed to prevent diffusion of the second encapsulation layer 182. However, when the second encapsulation layer 182 overflows the dam DAM during a process, the second encapsulation layer 182 as an organic layer may be exposed to an outside, so that moisture or the like may invade the light-emitting element. Therefore, to prevent the invasion, at least ten dams DAM may be stacked.

Referring to FIG. 6, the dam DAM may be disposed on the protective film 145 and in the non-display area NA.

Further, the dam DAM, and the first middle layer 150 and the second middle layer 160 may be formed simultaneously. The first middle layer 150, and a lower layer of the dam DAM may be formed simultaneously. The second middle layer 160, and an upper layer of the dam DAM may be formed simultaneously. Thus, the dam DAM may have a double layer structure.

Accordingly, the dam DAM may be made of the same material as that of each of the first middle layer 150 and the second middle layer 160. However, implementations of the present disclosure are not limited thereto.

Referring to FIG. 6, the dam DAM may overlap the low-potential driving power line VSSL. For example, the low-potential driving power line VSSL may be formed in a layer under the dam DAM and in the non-display area NA.

The low-potential driving power line VSSL and a gate driver GIP in a form of a gate in panel (GIP) may surround a periphery of the display panel. The low-potential driving power line VSSL may be located outwardly of the gate driver GIP. Further, the low-potential driving power line VSSL may be connected to the anode electrode 171 to apply a common voltage thereto. The gate driver GIP is simply illustrated in plan and cross-sectional views. However, the gate driver GIP may be configured using a thin-film transistor TFT having the same structure as that of each of the thin-film transistors T4 and T6 of the display area AA.

Referring to FIG. 6, the low-potential driving power line VSSL is disposed outwardly of the gate driver GIP. The low-potential driving power line VSSL is disposed outwardly of the gate driver GIP and surrounds the display area AA. The low-potential driving power line VSSL may be made of the same material as that of each of the source and drain electrodes 140 and 240 of the light-emission and reset transistors T4 and T6. The present disclosure is not limited thereto. For example, the low-potential driving power line VSSL may be made of the same material as that of each of the fourth gate electrode 125 and the sixth gate electrode 225.

Further, the low-potential driving power line VSSL may be electrically connected to the anode electrode 171. Alternatively, the low-potential driving power line VSSL may be electrically connected to the cathode electrode 173. The low-potential driving power line VSSL may supply the low-potential driving voltage EVSS to the plurality of pixels in the display area AA.

A touch layer 190 may be disposed on the encapsulation layer 180. In the touch layer 190, a touch buffer film 191 may be positioned between a touch sensor metal including touch electrode connection lines 192 and 194 and touch electrodes 195 and 196 and the cathode electrode 173 of the light-emitting element EL.

The touch buffer film 191 may prevent chemical (developer, etchant, etc.) used in a manufacturing process of the touch sensor metal disposed on the touch buffer film 191 or moisture from the outside from invading the light-emitting layer 172 including an organic material. Accordingly, the touch buffer layer 191 may prevent damage to the light-emitting layer 172 as vulnerable to the chemicals or moisture.

The touch buffer film 191 may be made of an organic insulating material that may be formed at a low temperature below or equal to a certain temperature (100 degrees Celsius) to prevent damage to the light-emitting layer 172 including the organic material vulnerable to a high temperature, and that has a low dielectric constant of 1 to 3. For example, the touch buffer layer 191 may be made of an acryl-based, epoxy-based, or siloxane-based material. The touch buffer film 191 made of the organic insulating material and having planarization performance may prevent damage to the encapsulation layer 180 and fracture of the touch sensor metal formed on the touch buffer film 191 due to bending of the organic light-emitting display device.

According to a mutual-capacitance-based touch sensor structure, the touch electrodes 195 and 196 may be disposed on the touch buffer layer 191, and the touch electrodes 195 and 196 may be disposed to intersect each other.

The touch electrode connection lines 192 and 194 may electrically connect the touch electrodes 195 and 196 to each other. The touch electrode connection lines 192 and 194 and the touch electrodes 195 and 196 may be positioned on different layers while the touch insulating film 193 is interposed therebetween.

The touch electrode connection lines 192 and 194 may overlap the bank layer 165, thereby preventing an aperture ratio from being lowered.

In one example, a portion of the touch electrode connection line 192 may extend along upper and side surfaces of the encapsulation layer 180 and upper and side surfaces of the dam DAM and then may be electrically connected to a touch driver circuit (not shown) through a pad 198. Thus, the touch electrodes 195 and 196 may be electrically connected to the touch driver circuit.

The portion of the touch electrode connection line 192 may receive a touch driving signal from the touch driver circuit and transmit the same to the touch electrodes 195 and 196, and may receive a touch sensing signal from the touch electrodes 195 and 196 and may transmit the same to the touch driver circuit.

A touch protective film 197 may be disposed on the touch electrodes 195 and 196. In the drawing, it is shown that the touch protective film 197 is disposed only on the touch electrodes 195 and 196. However, implementations of the present disclosure are not limited thereto. The touch protective film 197 may extend to an inner end or an outer end of the dam DAM and thus may also be disposed on the touch electrode connection line 192.

Further, a color filter (not shown) may be further disposed on the encapsulation layer 180, and the color filter may be positioned on the touch layer 190 or between the encapsulation layer 180 and the touch layer 190.

In FIG. 6, the display device 100 of the display area AA may have a following stacked structure. The buffer layer 105 may be disposed on the substrate 10 including the display area AA and the non-display area NA, and the first insulating layer 110 may be disposed on the buffer layer 105. The fourth semiconductor layer 115 of the light-emission transistor T4 and the sixth semiconductor layer 215 of the reset transistor T6 may be disposed on the first insulating layer 110, and the second insulating layer 120 may be disposed on the first insulating layer 110, the fourth semiconductor layer, and the sixth semiconductor layer.

The low-potential driving power line VSSL, the fourth gate electrode 125 of the light-emission transistor T4, and a sixth gate electrode 225 of the reset transistor T6 may be disposed on the second insulating layer 120. The third insulating layer 135 may be disposed on the second insulating layer 120, the low-potential driving power line VSSL, the fourth gate electrode 125, and the sixth gate electrode 225. Although not shown in FIG. 6, both of the fourth gate electrode 125 and the sixth gate electrode 225 may contact a emission signal line.

The first electrode 140 and the second electrode 140 of the light-emission transistor T4 and the first electrode 240 and the second electrode 240 of the reset transistor T6 may be disposed on the third insulating layer 135. The first electrode 140 and the second electrode 140 of the light-emission transistor T4 may be in contact with the fourth semiconductor layer 115 via the first contact hole, and the first electrode 240 and the second electrode 240 of the reset transistor T6 may be in contact with the sixth semiconductor layer 215 via the second contact hole. The protective film 145 may be disposed on the third insulating layer 135, the first electrode 140 and the second electrode 140 of the light-emission transistor T4, and the first electrode 240 and the second electrode 240 of the reset transistor T6.

The first middle layer 150 may be disposed on the protective layer 145 in the display area AA, and the connection electrode 155 may be disposed on the first middle layer 150 in the display area AA. The connection electrode 155 may be in contact with the first electrode 140 or the second electrode 140 of the light-emission transistor T4 via the third contact hole 156 and may be in contact with the first electrode 240 or the second electrode 240 of the reset transistor T6 via the third contact hole 156. Although not shown in FIG. 6, the first electrode 140 or the second electrode 140 of the light-emission transistor T4 which is not connected to the connection electrode 155 may be in contact with the driving transistor. The first electrode 240 or the second electrode 240 of the reset transistor T6, which is not connected to the connection electrode 155 may be in contact with a reset voltage line. In the display area AA, the second middle layer 160 may be disposed on the first middle layer 150 and the connection electrode 155.

In the display area AA, the first electrode 171 of the light-emitting element EL may be disposed on the second middle layer 160. The first electrode 171 of the light-emitting element EL may be in contact with the connection electrode 155 via a fourth contact hole. The bank layer 165 may be disposed on the second middle layer 160 except for the first electrode 171 of the light-emitting element EL in the display area AA. In the display area AA, the light-emitting layer 172 may be disposed on the bank layer 165 and the first electrode 171 of the light-emitting element EL. The second electrode 173 of the light-emitting element EL may be disposed on the light-emitting layer 172 in the display area AA. The encapsulation layer 180 may be disposed on the second electrode 173 of the light-emitting element EL in the display area AA and the protective film 145 in the non-display area NA.

As described above, according to an implementation of the present disclosure, a display device including the structure capable of delaying or preventing moisture penetration in an area between the display area DA and the bendable area BA may be realized.

That is, according to an implementation of the present disclosure, the display device having the structure capable of delaying moisture from a portion of the planarization layer in the bendable area into a portion thereof in the display area in the portion of the non-display area between the display area and the bendable area, and having the waterproof line vertically protruding from the metal line to prevent the moisture penetration from a portion of the planarization layer in the bendable area into a portion thereof in the display area.

The display device according to various aspects and implementations of the present disclosure may be described as follows.

One aspect of the present disclosure provides a display device comprising: a substrate including a display area AA, a non-display area NA, and a bendable area BA; an insulating layer disposed on the substrate; a first connection line SD1 disposed on the substrate and the insulating layer; a first planarization layer PLN1 disposed on the insulating layer and the first connection line SD1; a second connection line SD2 disposed on the first planarization layer PLN1; a second planarization layer PLN2 disposed on the second connection line SD2 and the first planarization layer PLN1; a third planarization layer PDL disposed on a portion of the second planarization layer PLN2; a touch buffer layer T-BUF disposed on the second planarization layer PLN2 and the third planarization layer PDL; and a sealing layer disposed on the touch buffer layer T-BUF, wherein in a portion of the non-display area NA between the display area AA and the bendable area BA, a first groove via1 and a second groove via2 are defined in each of the touch buffer layer T-BUF and the second planarization layer PLN2 so as to be recessed downwardly from an upper surface of each of the touch buffer layer T-BUF and the second planarization layer PLN2, wherein the first and second grooves are adjacent to each other.

In accordance with some implementations of the display device of the present disclosure, in the portion of the non-display area NA between the display area AA and the bendable area BA, the second connection line SD2 is electrically connected to the first connection line SD1 via first and second through-holes vertically extending through the first planarization layer PLN1.

In accordance with some implementations of the display device of the present disclosure, in the portion of the non-display area NA between the display area AA and the bendable area BA, the second connection line SD2 includes a waterproof line vertically passing through a third through-hole vertically extending through the first planarization layer PLN1 so as to contact the insulating layer.

In accordance with some implementations of the display device of the present disclosure, the display device further comprises: a first insulating layer 11 as the insulating layer disposed on the substrate; a first data line GAT disposed on the first insulating layer 11; a second insulating layer 12 disposed on the first insulating layer 11 and the first data line GAT; a second data line OGAT1 disposed on the second insulating layer 12; a third insulating layer 13 disposed on the second insulating layer 12 and the second data line OGAT1; a third data line OGAT2 disposed on the third insulating layer 13; a fourth insulating layer 14 disposed on the third insulating layer 13 and the third data line OGAT2; the first connection line SD1 disposed on the fourth insulating layer 14; and a fifth insulating layer 15 disposed on the fourth insulating layer 14 and the first connection line SD1.

In accordance with some implementations of the display device of the present disclosure, in the portion of the non-display area NA between the display area AA and the bendable area BA, the first connection line SD1 is electrically connected to the third data line OGAT2 via a through-hole vertically extending through the fourth insulating layer 14, the first connection line SD1 is electrically connected to the second data line OGAT1 via a through-hole vertically extending through the fourth insulating layer 14 and the third insulating layer 13, the first connection line SD1 is electrically connected to the first data line GAT via a through-hole vertically extending through the fourth insulating layer 14, the third insulating layer 13, and the second insulating layer 12.

In accordance with some implementations of the display device of the present disclosure, the insulating layer includes an inorganic material.

In accordance with some implementations of the display device of the present disclosure, each of the first planarization layer PLN1 to the third planarization layer PDL includes an organic material.

In accordance with some implementations of the display device of the present disclosure, the substrate includes: a main area including the display area AA and the non-display area NA; the bendable area BA constructed to be bendable from the main area in a thickness direction of the display device; and a sub-area connected to the bendable area BA and opposite to the main area such that the bendable area BA is positioned between the sub-area and the main area.

In accordance with some implementations of the display device of the present disclosure, the display device further comprises a plurality of lines extending from the sub-area to the main area through the bendable area BA, wherein the plurality of lines includes: a first line to which a first voltage is applied; a second line to which a second voltage is applied; and a dummy line disposed between the first line and the second line, wherein a third voltage is applied to the dummy line.

In accordance with some implementations of the display device of the present disclosure, the display device further comprises a data driver disposed on the sub-area, wherein each of the first line and the second line is connected to the data driver.

In accordance with some implementations of the display device of the present disclosure, the non-display area NA surrounds the display area AA and is disposed outwardly of the display area AA, wherein a plurality of sub-pixels are disposed on the display area AA, wherein each of the plurality of sub-pixels includes at least one transistor.

In accordance with some implementations of the display device of the present disclosure, a crack detection pattern used to detect a state in which a crack occurs in the substrate is disposed in the non-display area NA so as to surround three sides of the display area AA.

In accordance with some implementations of the display device of the present disclosure, a low-potential power line is disposed between the crack detection pattern and the display area AA so as to surround the three sides of the display area AA.

In accordance with some implementations of the display device of the present disclosure, the display device further comprises a gate driver disposed on the non-display area NA and on each of both opposing side ends of the display area AA and configured to supply a gate signal or a scan signal to the display area AA.

In accordance with some implementations of the display device of the present disclosure, the non-display area NA includes a clad area on which a plurality of dams defining a position of an encapsulation layer for protecting a light-emitting element of the display area AA are disposed.

In accordance with some implementations of the display device of the present disclosure, the display device further comprises: a bendable portion disposed in the non-display area NA; a plurality of connection portions disposed between the bendable portion and the display area AA; a light-emitting layer connected to the transistor; an encapsulation layer disposed on the light-emitting layer; a touch electrode disposed on the encapsulation layer; a touch planarization layer disposed on the touch electrode; and a partition wall disposed between the plurality of connection portions and the bendable portion.

In accordance with some implementations of the display device of the present disclosure, the touch electrode includes a first touch electrode and a second touch electrode, wherein a touch buffer layer T-BUF is disposed on the encapsulation layer, wherein the first touch electrode is disposed on the touch buffer layer T-BUF, wherein a touch insulating layer is disposed on the touch buffer layer T-BUF and the first touch electrode, wherein the second touch electrode is disposed on the touch insulating layer.

In accordance with some implementations of the display device of the present disclosure, each of source and drain electrodes of the at least one transistor are formed of the same material as the first connection SD1 and are disposed in the same layer.

In accordance with some implementations of the display device of the present disclosure, the display device further comprises a bendable protective layer disposed on the bendable area BA, wherein the bendable protective layer vertically overlaps the partition wall.

In accordance with some implementations of the display device of the present disclosure, the display device further comprises a display panel disposed on the substrate, wherein one side edge of the display panel is bendable in a rear direction so as to have a predetermined curvature in the bendable area BA, wherein the bendable protective layer is disposed on an outer edge area of the display panel in the bendable area BA in a state in which the display panel has been bent.

Although some implementations of the present disclosure have been described above with reference to the accompanying drawings, the present disclosure may not be limited to some implementations and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some implementations as described above are not restrictive but illustrative in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area, a non-display area, and a bendable area;
an insulating layer on the substrate;
a first connection line on the substrate and the insulating layer;
a first planarization layer on the insulating layer and the first connection line;
a second connection line on the first planarization layer;
a second planarization layer on the second connection line and the first planarization layer;
a third planarization layer on a portion of the second planarization layer;
a touch buffer layer on the second planarization layer and the third planarization layer; and
a sealing layer on the touch buffer layer,
wherein between the display area and the bendable area, a first groove and a second groove are formed in each of the touch buffer layer and the second planarization layer so as to be recessed downwardly from an upper surface of each of the touch buffer layer and the second planarization layer, and
wherein the first and second grooves are adjacent to each other.

2. The display device of claim 1, wherein between the display area and the bendable area, the second connection line is electrically connected to the first connection line via first and second through-holes vertically extending through the first planarization layer.

3. The display device of claim 2, wherein in the portion of the non-display area between the display area and the bendable area, the second connection line includes a waterproof line vertically passing through a third through-hole vertically extending through the first planarization layer so as to contact the insulating layer.

4. The display device of claim 1, wherein the insulating layer includes:
a first insulating layer on the substrate;
a first data line on the first insulating layer;
a second insulating layer on the first insulating layer and the first data line;
a second data line on the second insulating layer;
a third insulating layer on the second insulating layer and the second data line;
a third data line on the third insulating layer;
a fourth insulating layer on the third insulating layer and the third data line;
the first connection line on the fourth insulating layer; and
a fifth insulating layer on the fourth insulating layer and the first connection line.

5. The display device of claim 4, wherein in the portion of the non-display area between the display area and the bendable area,
the first connection line is electrically connected to the third data line via a through-hole vertically extending through the fourth insulating layer,
the first connection line is electrically connected to the second data line via a through-hole vertically extending through the fourth insulating layer and the third insulating layer,
the first connection line is electrically connected to the first data line via a through-hole vertically extending through the fourth insulating layer, the third insulating layer, and the second insulating layer.

6. The display device of claim 1, wherein the insulating layer includes an inorganic material.

7. The display device of claim 1, wherein each of the first planarization layer to the third planarization layer includes an organic material.

8. The display device of claim 1, wherein the substrate includes:
a main area including the display area and the non-display area;
the bendable area constructed to be bendable from the main area in a thickness direction of the display device; and
a sub-area connected to the bendable area and opposite to the main area such that the bendable area is positioned between the sub-area and the main area.

9. The display device of claim 8, wherein the display device further comprises a plurality of lines extending from the sub-area to the main area through the bendable area,
wherein the plurality of lines includes:
a first line to which a first voltage is applied;
a second line to which a second voltage is applied; and
a dummy line disposed between the first line and the second line, wherein a third voltage is applied to the dummy line.

10. The display device of claim 9, wherein the display device further comprises a data driver on the sub-area,
wherein each of the first line and the second line is connected to the data driver.

11. The display device of claim 1, wherein the non-display area surrounds the display area and is disposed outwardly of the display area,
wherein a plurality of sub-pixels are on the display area, wherein each of the plurality of sub-pixels includes at least one transistor.

12. The display device of claim 1, further comprising a crack detection pattern used to detect a state in which a crack occurs in the substrate being disposed in the non-display area so as to surround three sides of the display area.

13. The display device of claim 12, wherein a low-potential power line is between the crack detection pattern and the display area so as to surround the three sides of the display area.

14. The display device of claim 1, wherein the display device further comprises a gate driver on the non-display area and on each of both opposing side ends of the display area and configured to supply a gate signal or a scan signal to the display area.

15. The display device of claim 1, wherein the non-display area includes a clad area on which a plurality of dams defining a position of an encapsulation layer for protecting a light-emitting element of the display area are disposed.

16. The display device of claim 11, wherein the display device further comprises:
a bendable portion disposed in the non-display area;
a plurality of connection portions between the bendable portion and the display area;
a light-emitting layer connected to the transistor;
an encapsulation layer on the light-emitting layer;
a touch electrode on the encapsulation layer;
a touch planarization layer on the touch electrode; and
a partition wall between the plurality of connection portions and the bendable portion.

17. The display device of claim 16, wherein the touch electrode includes a first touch electrode and a second touch electrode,
wherein a touch buffer layer is on the encapsulation layer,
wherein the first touch electrode is on the touch buffer layer,
wherein a touch insulating layer is on the touch buffer layer and the first touch electrode,
wherein the second touch electrode is on the touch insulating layer.

18. The display device of claim 11, wherein a source and drain electrodes of the at least one transistor are formed of the same material as the first connection line and are disposed in the same layer.

19. The display device of claim 16, wherein the display device further comprises a bendable protective layer on the bendable area,
wherein the bendable protective layer vertically overlaps the partition wall.

20. The display device of claim 19, wherein the display device further comprises a display panel on the substrate, wherein one side edge of the display panel is bendable in a rear direction so as to have a selected curvature in the bendable area,
wherein the bendable protective layer is on an outer edge area of the display panel in the bendable area in a state in which the display panel has been bent.
